(19) United States
(12) Patent Application Publication
(10) Pub. No.: US 2014/0042617 A1
(43) Pub. Date: Feb. 13, 2014

(54) SEMICONDUCTOR DEVICE HAVING PENETRATION ELECTRODE

(71) Applicant: Elpida Memory, Inc., Tokyo (JP)

(72) Inventor: Shirou UCHIYAMA, Tokyo (JP)

(73) Assignee: Elpida Memory, Inc., Tokyo (JP)

(21) Appl. No.: 13/961,225

(22) Filed: Aug. 7, 2013

(30) Foreign Application Priority Data
Aug. 13, 2012 (JP) 2012-179379

(51) Int. Cl. H01L 23/538

(52) U.S. Cl. CPC H01L 23/5384
USPC 257/737; 257/774

(57) ABSTRACT

Disclosed herein is a semiconductor device that includes: a semiconductor substrate including first and second surfaces opposed to each other, a plurality of penetration electrodes each penetrating between the first and second surfaces and a plurality of first metal films each surrounding an associated one of the penetration electrodes with an intervention of an insulating film; and a wiring structure formed on a side of the first surface of the semiconductor substrate, the wiring structure including a plurality of wirings each electrically connected to an associated one of the penetration electrodes.

### BACKGROUND OF THE INVENTION

1. Field of the Invention

The present invention relates to a semiconductor device, and more particularly relates to a semiconductor device having penetration electrodes such as through silicon vias.

2. Description of Related Art

A so-called multi-chip module is known as an example of a semiconductor device including a plurality of three-dimensionally stacked semiconductor chips. In a general multi-chip module, semiconductor chips are three-dimensionally stacked and pad electrodes of the respective semiconductor chips and a module substrate are connected by means of a bonding wire, or the like.

In recent years, a type of a semiconductor device is also proposed in which semiconductor chips are three-dimensionally stacked and vertically-adjacent ones of the semiconductor chips are electrically connected with penetration electrodes such as through silicon vias that penetrate through the semiconductor chips (see Japanese Patent Application Laid-open No. 2008-300782). Because a bonding wire or the like not used in this type of semiconductor device, the mounting size can be reduced and the number of input/output signals can be greatly increased.

In the semiconductor device described in Japanese Patent Application Laid-open No. 2008-300782, penetration electrodes 14 and a silicon substrate 11 are separated by a resin layer 25 (see FIG. 13). In this structure, the resin layer functions as a capacitance dielectric film and parasitic capacitance occurs between the penetration electrodes and the silicon substrate. Accordingly, a noise occurring when a signal passes through a penetration electrode is transmitted from the resin layer to the silicon substrate and further to another penetration electrode, which may deteriorate the signal quality. Furthermore, the parasitic capacitance greatly changes according to an impurity concentration or the like of the silicon substrate.

### SUMMARY

In one embodiment of the present invention, there is provided a semiconductor device that includes: a semiconductor substrate including first and second surfaces opposed to each other, a plurality of penetration electrodes each penetrating between the first and second surfaces and a plurality of first metal films each surrounding an associated one the penetration electrodes with an intervention of an insulating film; and a wiring structure formed on a side the first surface of the semiconductor substrate, the wiring structure including a plurality of wirings each electrically connected to an associated one of the penetration electrodes.

In another embodiment of the present invention, there is provided a semiconductor device that includes: a semiconductor substrate including first and second surfaces opposed to each other and a plurality of through holes penetrating from the first surface to the second surface; a plurality of penetration electrodes, each of the penetration electrodes being formed in an associated one of the through holes; and a plurality of first films of metal, each of the first films being formed in the associated one of the through holes, surrounding a corresponding one of the penetration electrodes with an intervention of an insulating film.

In still another embodiment of the present invention, there is provided a semiconductor device that includes: a semiconductor substrate having a plurality of through holes that penetrate through the semiconductor substrate; a plurality of first metal films of a cylindrical structure each having an inner surface and an outer surface, the outer surface of each of the first metal films covering a surface of an associated one of the through holes; a plurality of insulating films of a cylindrical structure each having an inner surface and an outer surface, the outer surface of each of the insulating films covering the inner surface of an associated one of the first metal film; and a plurality of penetration electrodes each surrounded by the inner surface of an associated one of the insulating films.

According to the present invention, in the semiconductor device having a plurality of penetration electrodes, the quality of signal transmission is improved.

### BRIEF DESCRIPTION OF THE DRAWINGS

FIG. 1 is a schematic diagram of a semiconductor device according to an embodiment of the present invention;

FIG. 2 is a cross-sectional view of an interposer according to a first embodiment of the present invention;

FIG. 3 is a process (first process) of manufacturing the interposer according to the first embodiment;

FIG. 4 is a process (second process) of manufacturing the interposer according to the first embodiment;

FIG. 5 is a process (third process) of manufacturing the interposer according to the first embodiment;

FIG. 6 is a process (fourth process) of manufacturing the interposer according to the first embodiment;

FIG. 7 is a process (fifth process) of manufacturing the interposer according to the first embodiment;

FIG. 8 is a process (sixth process) of manufacturing the interposer according to the first embodiment;

FIG. 9 is a process (seventh process) of manufacturing the interposer according to the first embodiment;

FIG. 10 is a process (electrolytic plating) of manufacturing the interposer according to the first embodiment;

FIG. 11 is a cross-sectional view of the interposer according to a second embodiment of the present invention;

FIG. 12 is a process (first process) of manufacturing the interposer according to the second embodiment;

FIG. 13 is a process (second process) of manufacturing the interposer according to the second embodiment;

FIG. 14 is a process (third process) of manufacturing the interposer according to the second embodiment;

FIG. 15 is a process (fourth process) of manufacturing the interposer according to the second embodiment;

FIG. 16 is a process (fifth process) of manufacturing the interposer according to the second embodiment;

FIG. 17 is a process (sixth process) of manufacturing the interposer according to the second embodiment; and

FIG. 18 is a process (seventh process) of manufacturing the interposer according to the second embodiment.

### DETAILED DESCRIPTION OF THE EMBODIMENTS

The following detailed description refers to the accompanying drawings that show, by way of illustration, specific aspects and embodiments in which the present invention may be practiced. These embodiments are described in sufficient detail to enable those skilled in the art to practice the present invention. Other embodiments may be utilized, and structure, logical and electrical changes may be made without departing from the scope of the present invention. The various embodiments disclosed herein are not necessarily mutually exclusive, as some disclosed embodiments can be combined with one or more other disclosed embodiments to form new embodiments.

To decrease transmission of a noise from a penetration electrode to another penetration electrode, it is considered effective to fix the silicon substrate to a predetermined potential such as ground potential without being a floating potential to the silicon substrate. However, because the silicon substrate has semiconductor characteristics, a great noise may occur some frequency bands. Note that a penetration electrode may be called through silicon via, penetration via, through electrode, or through-via.

In order to supply a fixed potential to the silicon substrate, the silicon substrate need to be connected to contact plugs or contact terminals. When the contact plugs are made of a low-resistance metal material, a barrier film or the like needs to be formed between the contact plugs and the silicon substrate, which complicates the manufacturing.

Exemplary embodiments of the present invention are explained in detail below with reference to the accompanying drawings. While the embodiments are explained with a semiconductor device including semiconductor chips such as a DRAM (Dynamic Random Access Memory) mounted on an interposer, the semiconductor chips are not limited to a DRAM and include also a SRAM, which is also a volatile memory, a nonvolatile memory (such as a flash memory, a ReRAM, and a PRAM), a controller or the like, and a combination thereof.

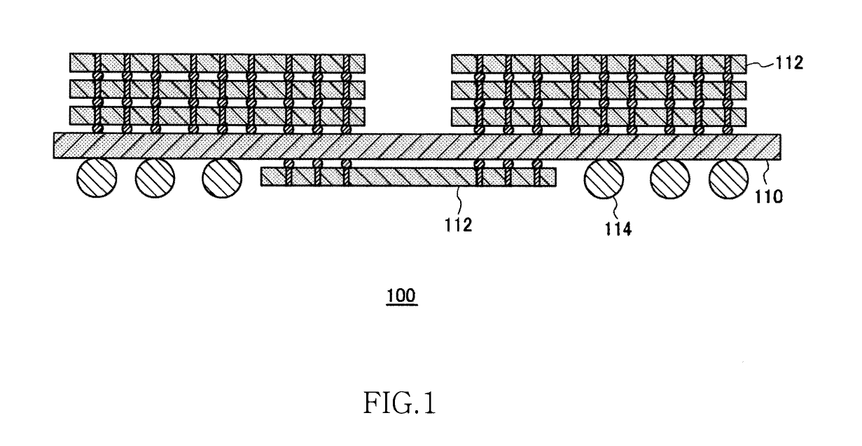

Referring now to FIG. 1, the semiconductor device 100 according to one embodiment of the present invention includes a plurality of semiconductor chips 112 stacked on both surfaces of an interposer 110. Each of the semiconductor chips 112 may function as a logic chip or a memory chip. In an example shown in FIG. 1, the semiconductor chips 112 mounted above the interposer 110 are memory chips; and the semiconductor chips 112 mounted under the interposer 110 are logic chips that controls the memory chips. The interposer 110 is made of a semiconductor substrate such as silicon to secure mechanical strength of the semiconductor device 100 and to function as a redistribution substrate for enlarging an electrode pitch.

External terminals 114 are provided on the bottom surface of the interposer 110. The external terminals 114 are electrically connected to the semiconductor chips 112 with penetration electrodes (not shown, details thereof are explained later) that penetrate through the interposer 110.

When a stacked body of the semiconductor chips 112 is mounted at a plurality of positions on the top surface of the interposer 110 as shown in FIG. 1, the size of the interposer 110 is also increased and thus the interposer 110 is likely to warp. However, with the semiconductor substrate according the present embodiment, warp is suppressed even in such a large interposer 110 (details and reasons thereof are explained later) and occurrence of a noise caused by signal transmission through one penetration electrode is also suppressed.

### First Embodiment

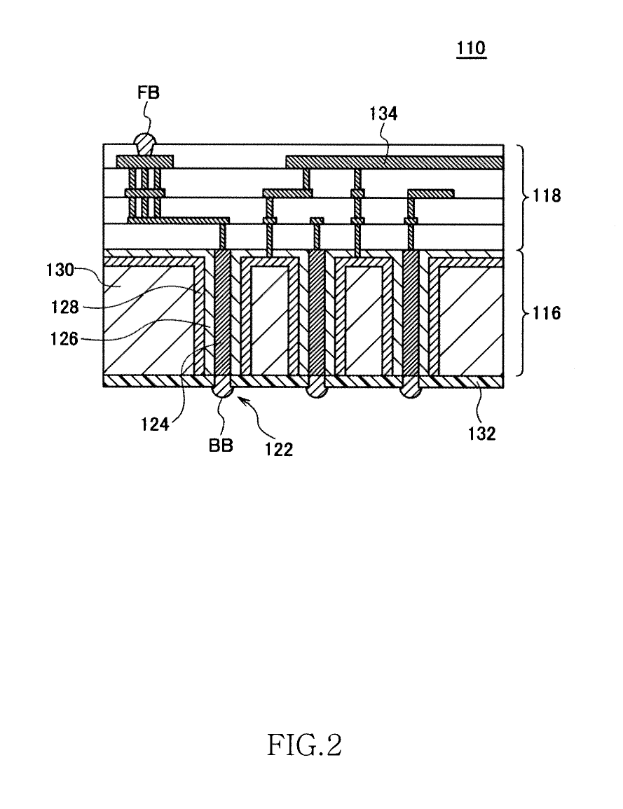

Turning to FIG. 2, the interposer 110 includes a substrate layer 116 and a multilevel wiring layer 118. A plurality of penetration electrodes 124 are formed in the substrate layer 116. Plural wirings included in the multilevel wiring layer 118 are connected to the penetration electrodes 124. A lower portion (on a rear surface side) of each of the penetration electrodes 124 included in the substrate layer 116 is connected to a back bump BB penetrating through a passivation film 132. An upper portion (on a front surface side) of each of the penetration electrodes 124 is connected to a front bump FB via a wiring in the multilevel wiring layer 118. A wiring pitch of the front bumps FB and the back bumps BB can be arbitrarily designed.

The substrate layer 116 includes a silicon substrate 130. A plurality of through holes 122 penetrating through the silicon substrate 130 are provided in the silicon substrate 130. An inner wall of each of the through holes 122 and an upper surface (first surface) of the silicon substrate 130 are covered with a metal film 128 and further covered with an oxide film (an insulating film) 126. That is, the oxide film 126 and the metal film 128 are interposed between the penetration electrodes 124 and the silicon substrate 130 thereby the penetration electrodes 124 and the silicon substrate 130 are electrically separated by the oxide film 126. The metal film 128 may be made of Cu, Ni, or the like. The penetration electrodes 124 may also be made of metal material such as Cu.

A ground potential wiring 134 (hereinafter, also “ground wire 134”) included in the multilevel wiring layer 118 is not directly connected to the silicon substrate 130 but is connected to the metal film 128 that covers the silicon substrate 130. The ground potential wiring 134 is also electrically connected to one (not shown) of the penetration electrodes 124 to supply the potential.

Also in the interposer 110 shown in FIG. 2, it is not that parasitic capacitance never occurs between the penetration electrodes 124 and the silicon substrate 130. However, because the metal film 128 located therebetween is fixed to the ground potential, the penetration electrodes 124 are guarded from the parasitic capacitance. In other words, influence of semiconductor characteristics of the silicon substrate 130 on the penetration electrodes 124 is suppressed by covering the silicon substrate 130 with the ground-potential metal film 128. Influence of semiconductor characteristics of the silicon substrate 130 on the ground wire 134 is similarly blocked. With this structure, a noise caused by signal transmission through one of the penetration electrodes 124 is not easily transmitted to another penetration electrode 124.

Because it suffices to connect the ground wire 134 to the broad metal film 128, the ground wire 134 has a larger contact margin and is easier to manufacture. Furthermore, a barrier film or the like for connecting the silicon substrate 130 and the ground wire 134 is unnecessary.

A process of manufacturing the interposer 110 according to the first embodiment is explained next.

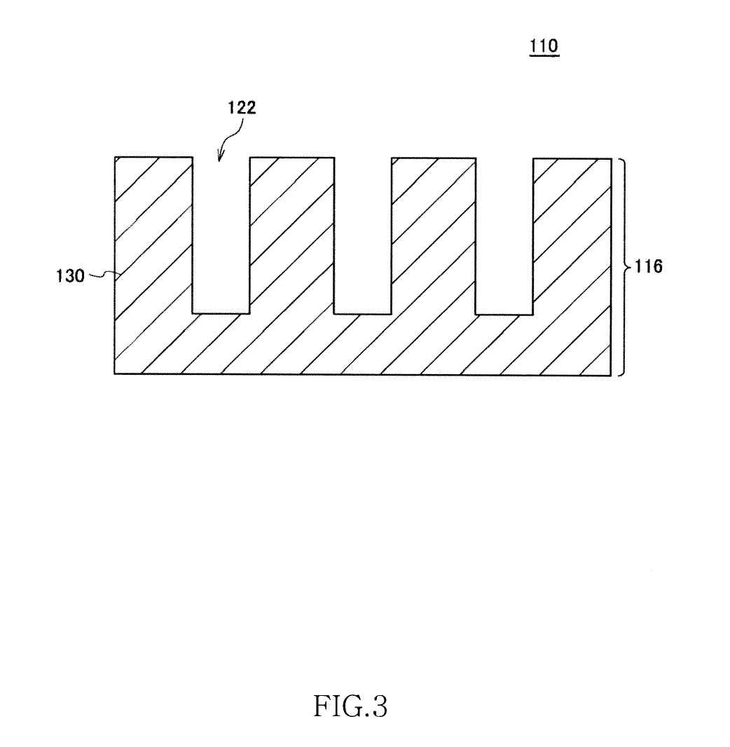

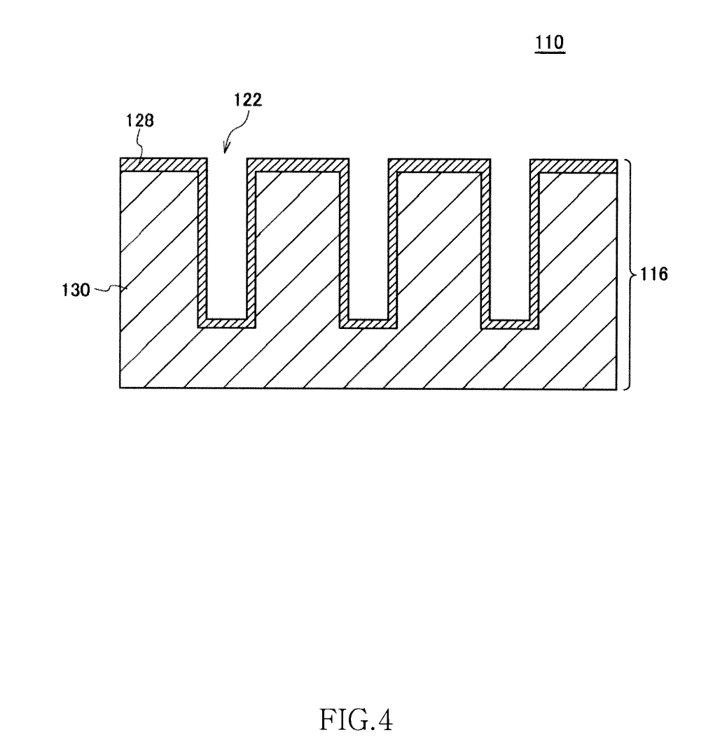

Turning to FIG. 3, the through holes 122 are first formed in the silicon substrate 130 by anisotropic etching using a resist film (not shown in FIG. 3). At this stage, however, the through holes 122 do not penetrate through the silicon substrate 130. As shown in FIG. 4, the metal film 128 is then formed on the inner walls of the through holes 122 and on the top surface of the silicon substrate 130.

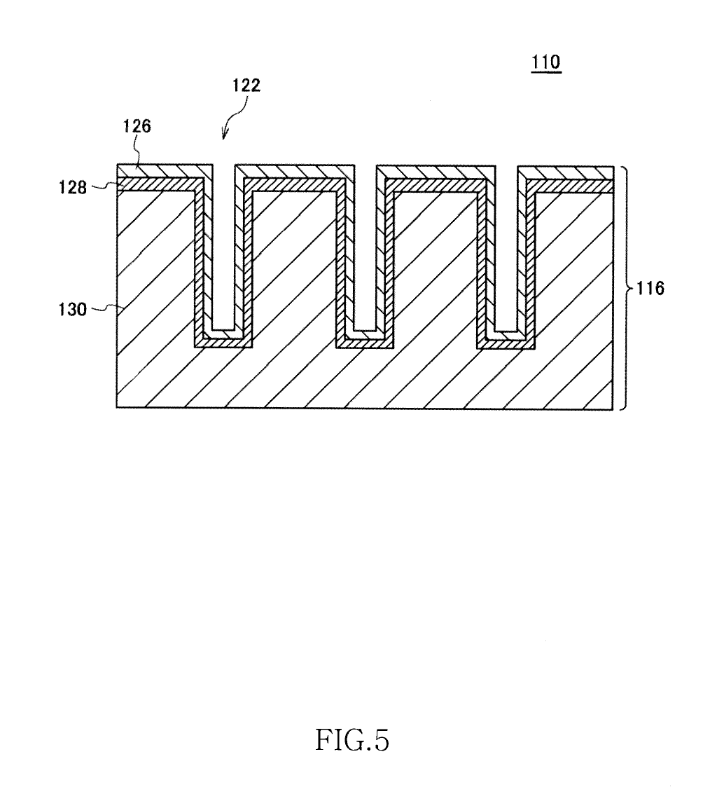

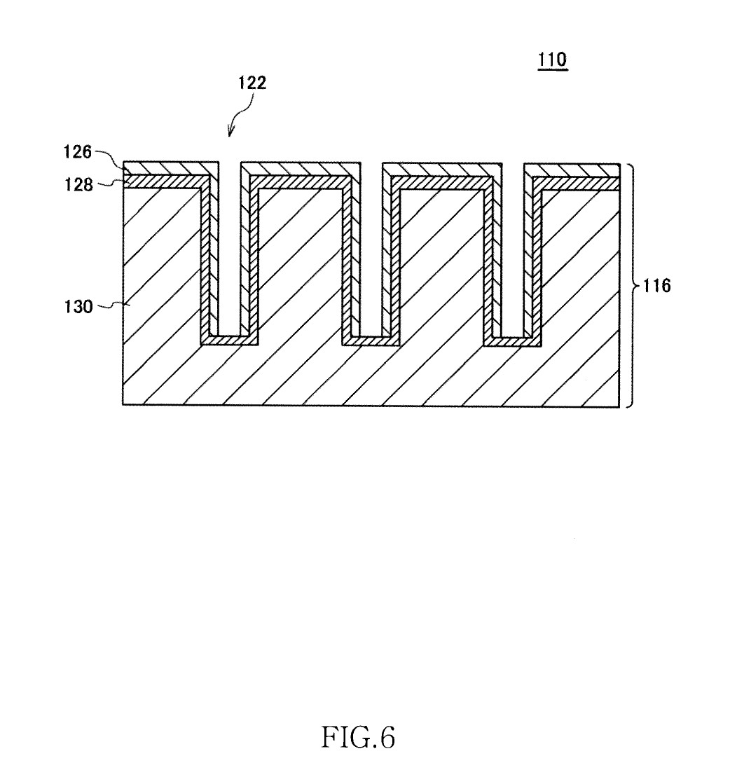

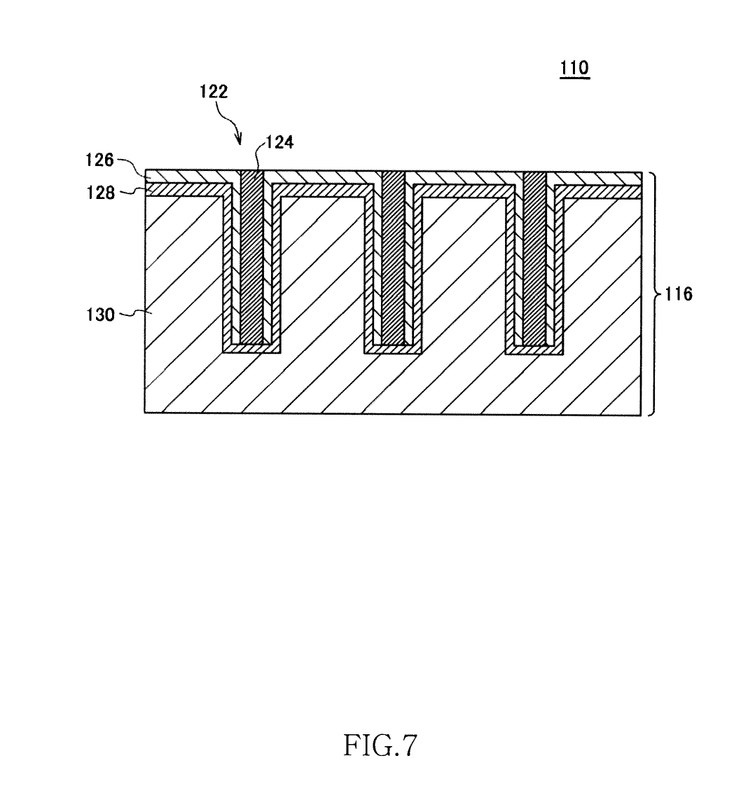

As shown in FIG. 5, the oxide film 126 is further formed on the inner walls of the through holes 122 and the top surface of the silicon substrate 130. Next, as shown in FIG. 6, the oxide film 126 (the insulating film) formed on the bottoms of the through holes 122 is etched back to partially expose the metal film 128 in the through holes 122. As shown in FIG. 7, a metal material such as Cu is then filled in the through holes 122 by an electroless plating method. Accordingly, the penetration electrodes 124 are formed inside the through holes 122.

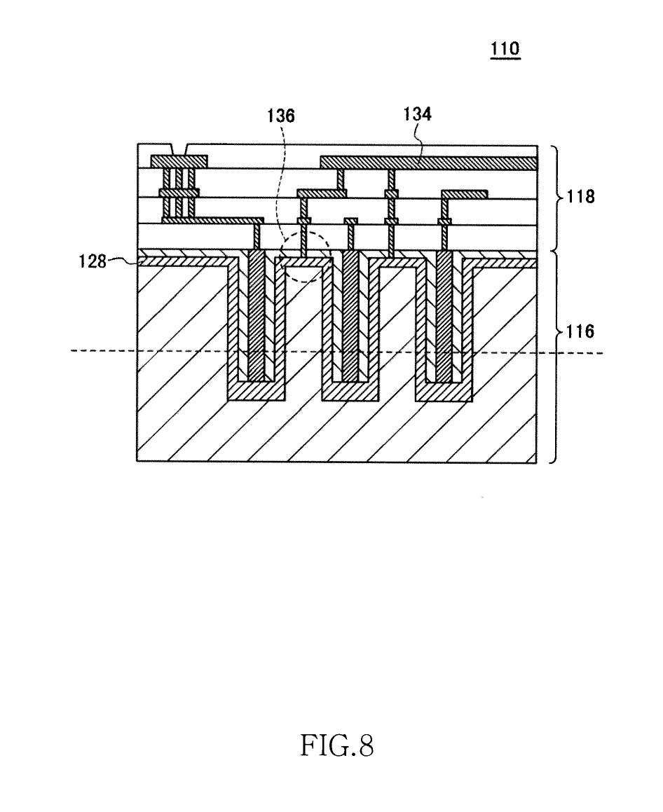

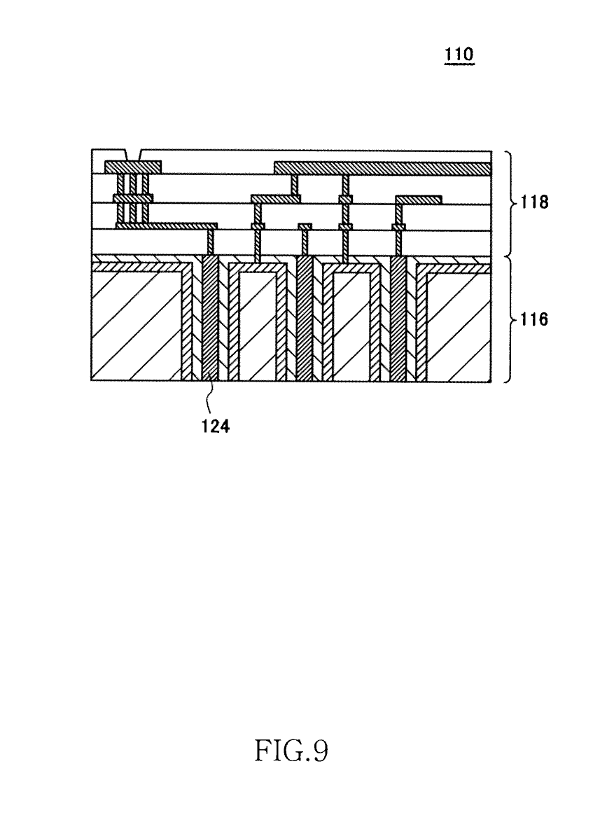

Turning to FIG. 8, the multilevel wiring layer 118 is formed on the substrate layer 116 by a known method. At that time, the ground wire 134 and the metal film 128 are connected in a connection region 136. As shown in FIG. 9, the lower surface of the substrate layer 116 is then ground to expose the penetration electrodes 124 from the lower surface thereof. The passivation film 132 and the back bumps BB are then formed, thereby completing the interposer 110 shown in FIG. 2.

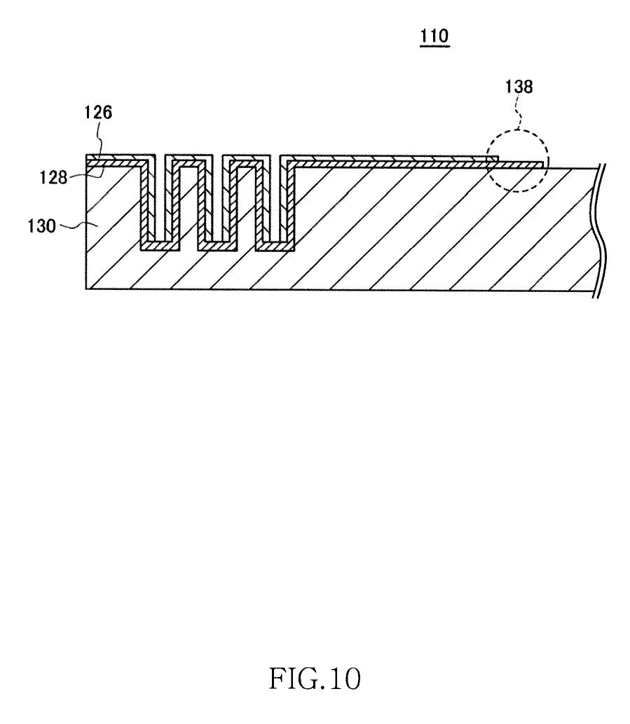

While the penetration electrodes 124 are formed by electroless plating in the first embodiment, the penetration electrodes 124 can be formed by electrolytic plating, not by electroless plating. In this case, a part of the oxide film 126 should be removed to expose a part of the metal film 128 from beneath the oxide film 126 as shown in FIG. 10, thereby forming a contact region 138. When a current is flowed to the metal film 128 via the contact region 138, the penetration electrodes 124 can be grown by plating with the metal film 128 exposed at the bottoms of the through holes 122 functioning as a seed layer. Because it suffices to form the contact region 138 at an outer periphery of a wafer, patterning is unnecessary and thus the contact region 138 is easy to manufacture.

### Second Embodiment

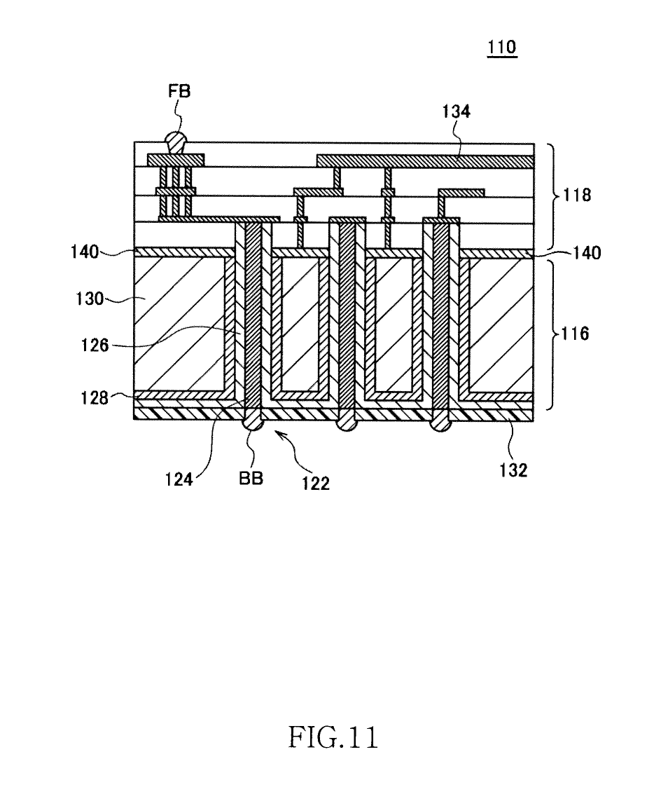

Turning to FIG. 11, the second embodiment of the present invention is different from the first embodiment in that a conductive layer 140 (metal such as Cu) is provided between the substrate layer 116 and the multilevel wiring layer 118. In the second embodiment, the through holes 122 are formed from the lower surface of the substrate layer 116, not from the upper surface thereof (details thereof are explained later). In the second embodiment, the ground wire 134 is connected to the conductive layer 140. Because the conductive layer 140 and the metal film 128 connected to the conductive layer 140 are fixed to the ground potential, the penetration electrodes 124 are easily guarded from the parasitic capacitance. As a result, a noise caused by signal transmission through one of the penetration electrodes 124 is not easily transmitted to another penetration electrode 124. Because the ground wire 134 is connected to the broad conductive layer 140, the ground wire 134 has a large contact margin and is easy to manufacture. In this way, also in the second embodiment, the noise can be effectively suppressed as in the first embodiment.

Furthermore, the substrate layer 116 according to the second embodiment is covered with the conductive layer 140 on the upper surface and covered with the metal film 128 on the lower surface. Because both of the surfaces are covered with metal films, stress balance is improved and mechanical strength against warp of the semiconductor substrate 120 caused by a difference in thermal expansion coefficients is further increased. Accordingly, even the large interposer 110 as shown in FIG. 1 has a structure without any defect of warp.

A process of manufacturing the interposer 110 according to the second embodiment is explained next.

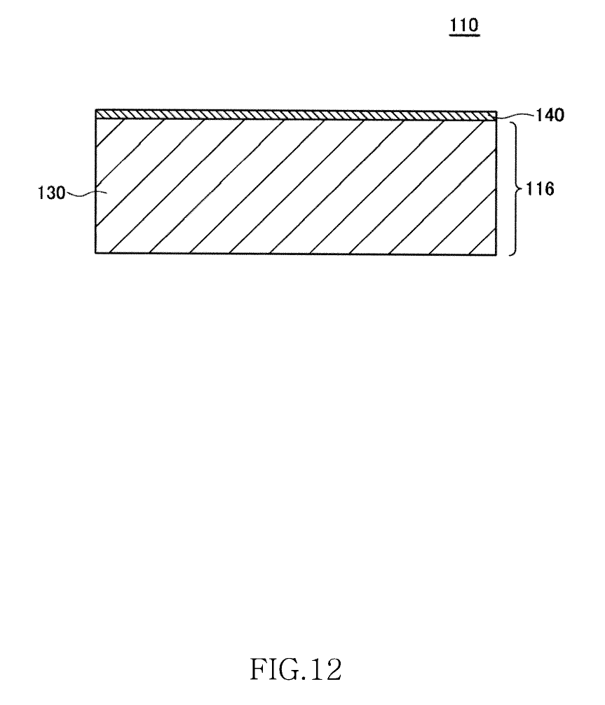

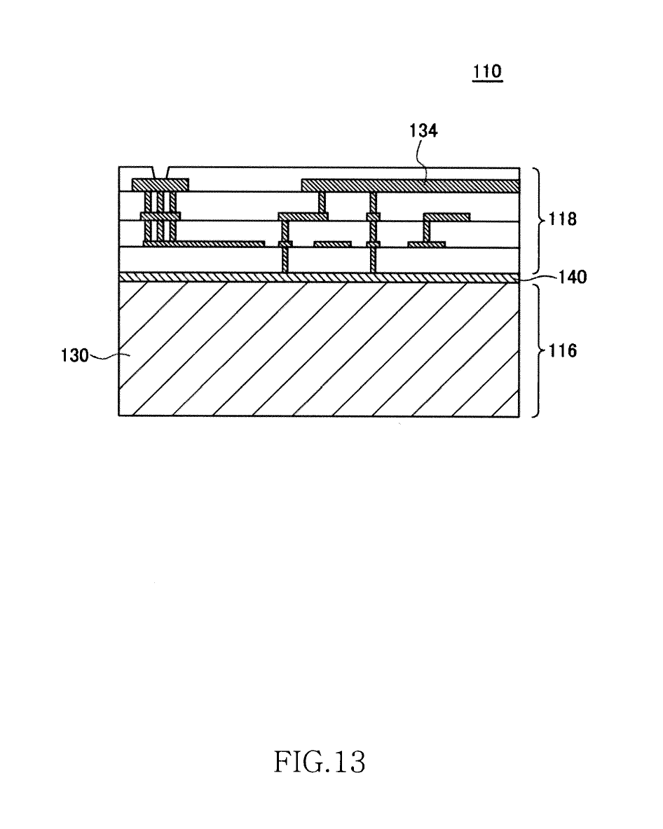

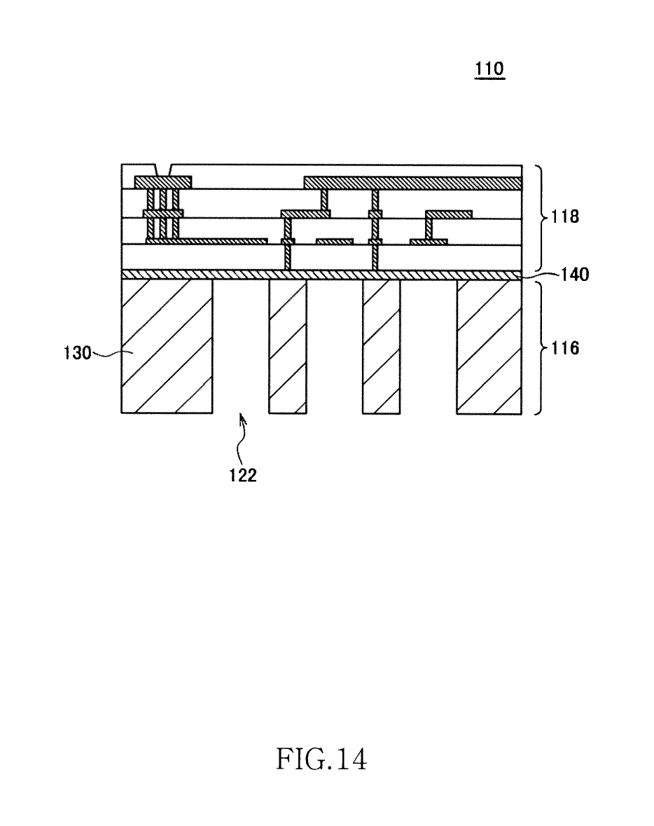

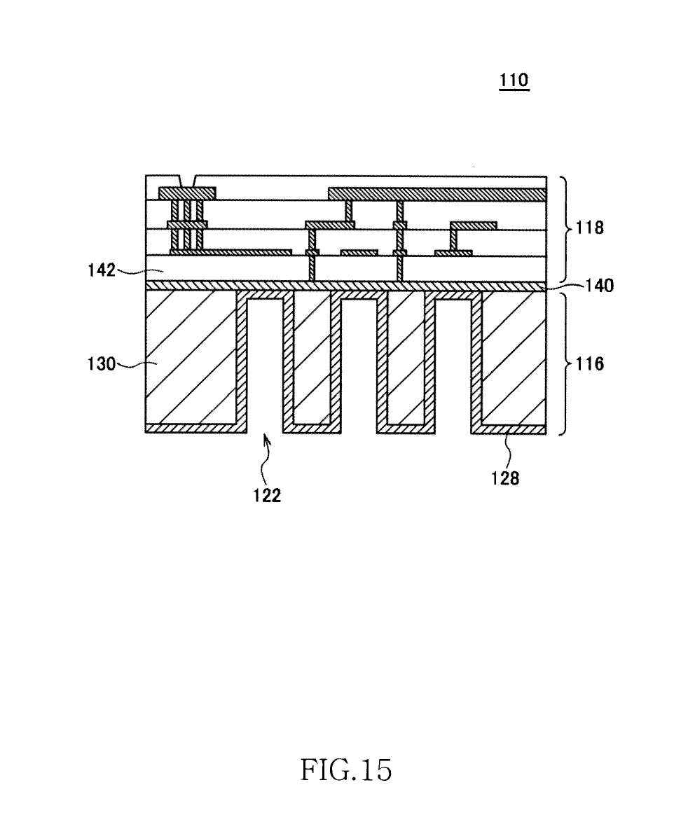

As shown in FIG. 12, the conductive layer 140 is first formed of a metal material such as Cu on the upper surface of the silicon substrate 130. Next, as shown in FIG. 13, the multilevel wiring layer 118 is further formed on the conductive layer 140. At that time, the ground wire 134 is connected to the conductive layer 140. As shown in FIG. 14, the through holes 122 then formed from the lower surface of the silicon substrate 130 by anisotropic etching using a resist film (not shown in FIG. 14). At that time, the conductive layer 140 functions as an etching stopper. As shown in FIG. 15, the metal film 128 is then formed on the inner walls of the through holes 122 and on the lower surface of the silicon substrate 130.

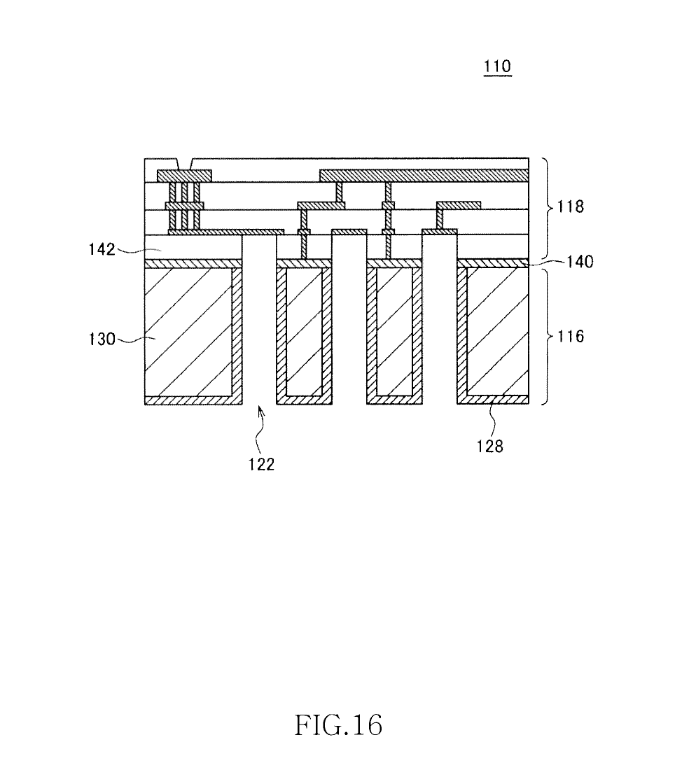

As shown in FIG. 16, the metal film 128 and the conductive layer 140 formed on the bottoms of the through holes 122, that is, on the side of the upper surface of the substrate layer 116 are then removed and further an insulating layer 142 of the multilevel wiring layer 118 is etched back. In this way, some parts of the wirings included in the multilevel wiring layer 118 are exposed at the bottoms of the through holes 122.

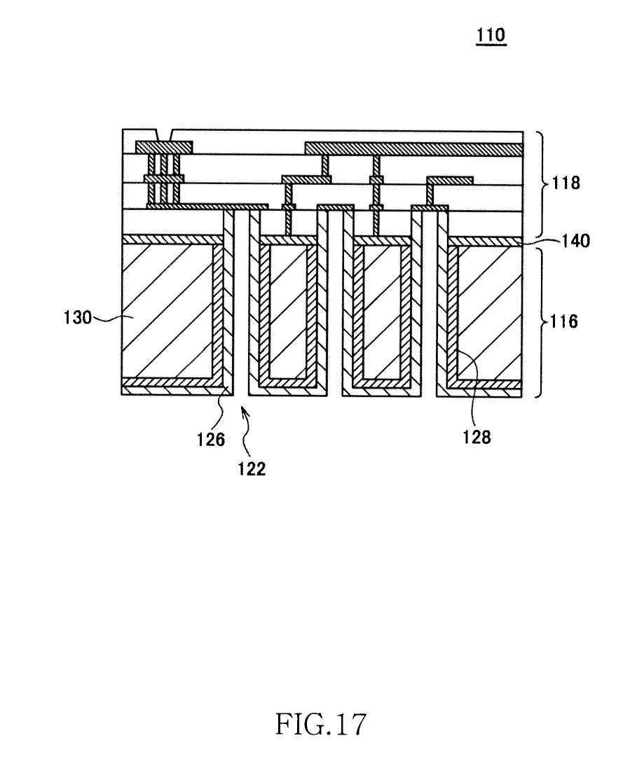

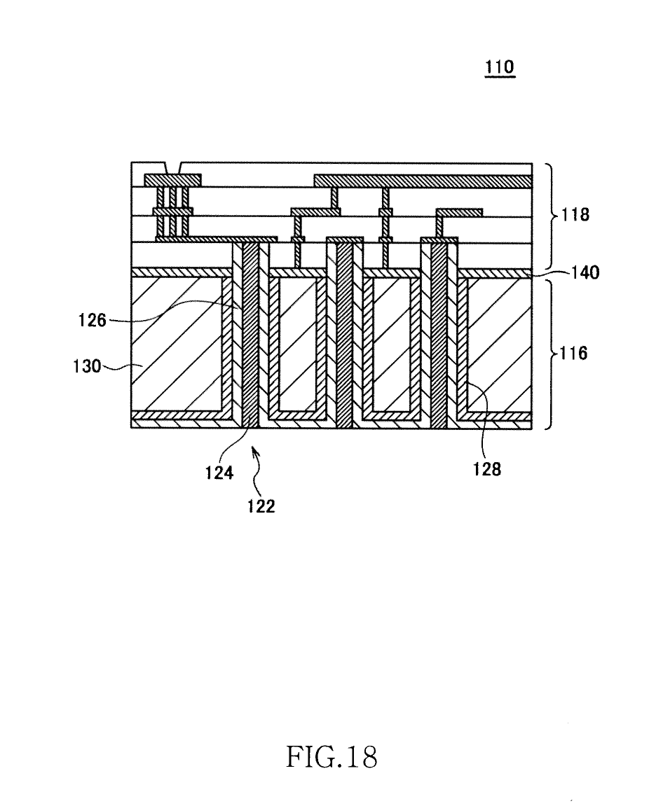

As shown in FIG. 17, the oxide film 126 is further formed on the inner walls of the through holes 122 and on the lower surface of the silicon substrate 130. The oxide film 126 formed on the bottom surface of the through holes 122 is etched back to expose again the wirings in the multilevel wiring layer 118. Then, as shown in FIG. 18, a metal material such as Cu is filled in the through holes 122 by an electroless plating method. In this way, the penetration electrodes 124 are formed inside the through holes 122. The passivation film 132 and the back bumps BB are then formed, thereby completing the interposer 110 shown in FIG. 11.

The interposer 110 having the penetration electrodes 124 has been explained in the first and second embodiments. By covering both or one of the upper and lower surfaces of the silicon substrate 130 with a metal material and supplying a fixed potential such as the ground potential to the metal film 128 or the conductive layer 140, noise transmission from one of the penetration electrodes 124 to another penetration electrode 124 is suppressed. Furthermore, warp of the interposer 110 is reduced by the metal film 128 or the conductive layer 140.

It is apparent that the present invention is not limited to the above embodiments, but may be modified and changed without departing from the scope and spirit of the invention.

In addition, while not specifically claimed in the claim section, the applicant reserves the right to include in the claim section of the application at any appropriate time the following methods:

A manufacturing method of a semiconductor device, the method comprising:

forming a trench a first surface of semiconductor substrate;

forming a metal film on an inner wall of the trench and on the first surface of the semiconductor substrate;

covering the metal film with an insulating film;

partially exposing the metal film formed inside the trench by etching back a part of the insulating film formed inside the trench;

forming an electrode by filling a metal material in the trench; and

forming a multilevel wiring structure on the first surface of the semiconductor substrate so that a wiring included in the multilevel wiring structure is electrically connected to the electrode.

B. A manufacturing method of a semiconductor device, the method comprising:

forming a conductive layer on a first surface of a semiconductor substrate;

forming a multilevel wiring structure having first and second wirings on the conductive layer;

forming a through hole from a second surface opposite to the first surface of the semiconductor substrate to expose a part of the conductive layer;

forming a metal film on an inner wall of the through hole and on the second surface of the semiconductor substrate to contact the conductive layer at a bottom of the through hole;

covering the metal film with an insulating film;

exposing the first wiring included in the multilevel wiring structure by etching back the multilevel wiring structure from the bottom of the through hole; and

forming a penetration electrode by filling a metal material in the through hole so that the penetration electrode is connected to the first wiring,

wherein the second wiring included in the multilevel wiring structure is electrically connected to the conductive layer.

What is claimed is:

1. A semiconductor device comprising:
a semiconductor substrate including first and second surfaces opposed to each other, a plurality of penetration electrodes each penetrating between the first and second surfaces and a plurality of first metal films each surrounding an associated one of the penetration electrodes with an intervention of an insulating film; and
a wiring structure formed on a side of the first surface of the semiconductor substrate, the wiring structure including a plurality of wirings each electrically connected to an associated one of the penetration electrodes.

2. The semiconductor device as claimed in claim 1, wherein the first metal films are supplied with a fixed potential in common.

3. The semiconductor device as claimed in claim 2, wherein the semiconductor substrate comprises a second metal film provided in parallel to the first and second surface and connected to each of the first metal films.

4. The semiconductor device as claimed in claim 3, wherein the second metal film is formed on the side of the first surface of the semiconductor substrate.

5. The semiconductor device as claimed in claim 4, wherein the semiconductor substrate further comprises a third metal film provided in parallel to the second metal film on a side of the second surface and connected to each of the first metal films.

6. The semiconductor device as claimed in claim 1, wherein the wiring structure including a third surface facing with the first surface of the semiconductor substrate and a fourth surface opposed to the third surface, the device further comprising:
a plurality of front bumps formed on the fourth surface of the wiring structure, each of the front bumps being electrically coupled to a corresponding one of the penetration electrodes; and
a plurality of back bumps formed on the second surface of the semiconductor substrate, each of the back bumps being electrically coupled to an associated one of the penetration electrodes.

7. A semiconductor device comprising:
a semiconductor substrate including first and second surfaces opposed to each other and a plurality of through holes penetrating from the first surface to the second surface;
a plurality of penetration electrodes, each of the penetration electrodes being formed in an associated one of the through holes; and
a plurality of first films of metal, each of the first films being formed in the associated one of the through holes, surrounding a corresponding one of the penetration electrodes with an intervention of an insulating film.

8. The semiconductor device as claimed in claim 7, further comprising a multilevel wiring structure provided on a side of the first surface, the multilevel wiring structure including upper and lower level wirings and an interlayer insulating film between the upper and lower level wirings, the upper and lower level wirings being electrically coupled to a corresponding one of the penetration electrodes.

9. The semiconductor device as claimed in claim 7, wherein the semiconductor substrate is free from a MOS transistor.

10. The semiconductor device as claimed in claim 7, wherein the first films are supplied with a fixed potential in common.

11. The semiconductor device as claimed in claim 7, further comprising a second film of metal formed on the first surface of the semiconductor substrate and connected to each of the first films.

12. The semiconductor device as claimed in claim 11, further comprising a third film of metal formed on the second surface of the semiconductor substrate and connected to each of the first films.

13. A semiconductor device comprising:
a semiconductor substrate having a plurality of through holes that penetrate through the semiconductor substrate;
a plurality of first metal films of a cylindrical structure each having an inner surface and an outer surface, the outer surface of each of the first metal films covering a surface of an associated one of the through holes;
a plurality of insulating films of a cylindrical structure each having an inner surface and an outer surface, the outer surface of each of the insulating films covering the inner surface of an associated one of the first metal film; and
a plurality of penetration electrodes each surrounded by the inner surface of an associated one of the insulating films.

14. The semiconductor device as claimed in claim 13, further comprising a second metal film that short-circuits the first metal films.

15. The semiconductor device as claimed in claim 14, wherein the semiconductor substrate has a first surface and a second surface opposite to each other, the second metal film is formed on the first surface of the semiconductor substrate.

16. The semiconductor device as claimed in claim 15, further comprising a third metal film that short-circuits the first metal films, the third metal film is formed on the second surface of the semiconductor substrate.
